(19) United States
(12) Patent Application Publication
(10) Pub. No.: US 2007/0144577 A1
(43) Pub. Date: Jun. 28, 2007

(54) Solar cell with physically separated distributed electrical contacts

(76) Inventors: George L. Rubin, Burnaby (CA); Andreas Schneider, Burnaby (CA); Leonid B. Rubin, Burnaby (CA)

Correspondence Address: KNOBBE MARTENS OLSON & BEAR LLP, 2040 MAIN STREET, FOURTEENTH FLOOR, IRVINE, CA, 92614, US

(21) Appl. No.: 11/317,530

(22) Filed: Dec. 23, 2005

(51) Int. Cl. H01L 31/00

(52) U.S. Cl. 136/256

(57) ABSTRACT

A photovoltaic apparatus has a semiconductor photovoltaic cell structure having a front surface and a back surface provided by respectively doped portions of semiconductor material forming a photovoltaic junction. A plurality of separate electrical contacts is embedded in the front side surface of the respective one of the portions of semiconductor material. The electrical contacts are distributed in two dimensions across the surface and are separated from each other and are in electrical contact with the respective one of the portions of semiconductor material. A back side electrical contact is provided on the back surface of the other of the respective portions of semiconductor material and in electrical contact therewith. A solar cell apparatus includes the apparatus above and electrodes for contacting the electrical contacts on the front and back side surfaces respectively of the semiconductor material.

### BACKGROUND OF THE INVENTION

1. Field of Invention

This invention relates to solar cells and more particularly to semiconductor photovoltaic cells and a process for forming electrical contacts in a solar cell structure.

2. Description of Related Art

It is well-known that under light illumination, photovoltaic (PV) solar cells comprising semiconductor wafers generate electric current. This electric current may be collected from the cell by means of front and back side metallization on the wafer which acts as electrical contacts on front and back sides of the solar cell. A partially electrically conductive paste, which typically contains silver and/or aluminum, is screen printed onto front and back surfaces of the cell through a mask. For the front (active) side of the solar cell structure, the mask typically has openings through which the paste contacts the surface to be metallized. The configuration of the openings determines the shape of a pattern that the paste will form on the surface of the cell and the ultimate shape of the electrical contacts. The front side mask is typically configured to produce a plurality of thin parallel line contacts and two or more thicker lines that are connected to and extend generally perpendicular to the parallel line contacts.

After spreading paste on the mask, the mask is removed and the wafer bearing the partially conductive paste is initially heated such that the paste dries. Later, the wafer is “fired” in an oven and the paste enters a metallic phase and at least part of it diffuses through the front side surface of the solar cell and into the cell structure while a portion is left solidified on the front side surface. The multiple thin parallel lines thus form thin parallel linear electrical contacts referred to as “fingers”, intersected by thicker perpendicular lines referred to as “bus bars”. The purpose of the fingers is to collect the electrical current from the front side of the PV cell. The purpose of the bus-bars is to receive the current from the fingers and transfer it away from the cell.

Typically, the width and the height of each finger is approximately 120 microns and 10 micron respectively. Inherent technical limitations of screen printing technology further introduce 1-10 micron fluctuations in finger height and 10-30 micron or greater fluctuations in width. While the fingers are sufficient to harvest small electric currents, the bus-bars are required to collect a much greater current from the plurality of fingers and therefore have a substantially larger cross section and width.

Back side metallization involves a layer of partially conductive paste containing aluminum over the entire back surface of the cell except for a few small areas. During the initial heating, the paste dries. Then silver/aluminum paste is screen printed in certain areas that have not been printed with aluminum paste and is further dried. Then, when the wafer is subjected to “firing”, wherein the aluminum paste forms a passivation layer called a Back Surface Field (BSF) and aluminum contacting layer and the silver/aluminum paste forms silver/aluminum pads. The aluminum contacting layer collects the electrical current from the PV cell itself and passes it to the silver pads. The silver/aluminum pads are used to take the electric current away from the PV cell.

The area that is occupied by the fingers and bus bars on the front side of the solar cell is known as the shading area and prevents solar radiation from reaching the solar cell surface. This shading area decreases solar cell conversion efficiency. Modern solar cell shading occupies 6-10% of the available solar cell surface area.

In addition, the presence of metallization on the front side and the silver/aluminum pads on the back side results in a decrease of voltage generated by the PV cell proportionate to the metallization area. Therefore, in order to achieve maximum conversion efficiency of the PV cell, it is desirable to minimize the area occupied by front side metallization. In addition, it is also desirable to minimize the area of silver metallization on the back side, in particular, to reduce the amount of silver/aluminum paste required. This will increase cell efficiency and will substantially decrease the cost of solar cell fabrication because silver/aluminum paste can be expensive.

The use of modern screen printing technology for front side metallization achieves a certain minimal level of metallization by optimizing widths and thicknesses of fingers and bus-bars for the solar cell being produced. However, there are principle limitations that prevent further decreases of the metallization area. Firstly, the cross sectional dimensions of the fingers cannot be less than certain dimensions in order to avoid excessive resistive losses due to electric current flow through the fingers during solar cell operation. In addition, bus bars are required to have minimum cross-sectional dimensions also to avoid resistive losses during operation. In addition, conventional technology does not allow eliminating the silver/aluminum pads on the rear side of the solar cell because PV module production requires the solar cells to be interconnected in-series via tinned copper tabs soldered to the silver/aluminum pads.

Several papers describe methods for printing very narrow fingers of ≦70 micron width (B. Raabe, F. Huster, M. McCann, P. Fath, HIGH ASPECT RATIO SCREEN PRINTED FINGERS, Proc. of the 20^{th} European Photovoltaic Solar Energy Conference, 6-10 Jun. 2005, Barcelona, Spain; Jaap Hoornstra, Arthur W. Weeber, Hugo H. C. de Moor, Wim C. Sinke, THE IMPORTANCE OF PASTE RHEOLOGY IN IMPROVING FINE LINE, THICK FILM SCREEN PRINTING OF FRONT SIDE METALLIZATION, Proc. of the 14^{th} European Photovoltaic Solar Energy Conference, 30.06-04.07 1997, Barcelona, Spain; and A. R. Burgers, H. H. C. de Moor, W. C. Sinke, P. P. Michiels, INTERRUPTION TOLERANCE OF METALLIZATION PATTERNS, Proc. of the 12^{th} European Photovoltaic Solar Energy Conference, 11-15 Apr. 1994, Amsterdam, The Netherlands). Unfortunately, conventional fingers of ≦70 microns have narrow cross sections that are too small to handle the necessary level of electric current capable of being produced by the solar cell without excessive resistive losses. In order to achieve adequate finger conductivity it may be necessary to either apply a second layer of screen printed paste on top of the first one or to apply a layer of metal on top of an initial screen printed metallization, using galvanic technology. The resulting cost and complexity of these methods add a prohibitively high expense to the production of photocells.

Heretofore, there appears to be no simple way to produce a photovoltaic solar cell having reduced front side shading and no conventional screen printed silver/aluminum pads on the back side.

### SUMMARY OF THE INVENTION

In accordance with one aspect of the invention, there is provided a photovoltaic apparatus. The apparatus includes a semiconductor photovoltaic cell structure having a front side surface and a back side surface provided by respectively doped portions of semiconductor material forming a photovoltaic junction. The apparatus further includes a plurality of electrical contacts embedded in the front surface of a respective one of the portions of semiconductor material, the electrical contacts being distributed in two dimensions across the surface and separated from each other and in electrical contact with the respective one of the portions of semiconductor material. The apparatus further includes a back side electrical contact on the back surface of the other of the respective portions of semiconductor material and in electrical contact therewith.

The electrical contacts may be distributed in two orthogonal directions across the surface.

The electrical contacts may be distributed evenly in the two orthogonal directions.

The electrical contacts may be arranged in an array.

The electrical contacts may be arranged in rows and columns.

Contacts of alternate rows may be arranged to lie in positions adjacent spaces between contacts in adjacent rows.

Generally each of the electrical contacts may have a contact surface facing generally normal to the front side surface and operable to be connected to a conductor.

The contact surface may have a generally rectangular shape.

The contact surface may have a generally circular shape.

The contact surface may have a star shape.

A solar cell apparatus may be made from the photovoltaic apparatus and may further include a first electrode for contacting the electrical contacts. The first electrode may include an electrically insulating optically transparent film having a surface, an adhesive layer on the surface of the film, at least one electrical conductor embedded into the adhesive layer, a conductor surface of the electrical conductor protruding from the adhesive layer, and an alloy bonding the electrical conductor to at least some of the electrical contacts such that current collected from the solar cell by the electrical contacts is gathered by the electrical conductor.

The electrical conductor may be connected to a common bus.

The electrical contacts may be arranged in rows and columns. The electrode may include a plurality of electrical conductors arranged in parallel spaced apart relation and the electrical conductors may be in contact with a plurality of the electrical contacts in a respective row or column.

Each of the electrical conductors may be connected to a bus.

The solar cell apparatus may further include a second electrode for contacting the back side electrical contact. The second electrode may include a second electrically insulating film having a second surface, a second adhesive layer on the second surface of the second film, at least one second electrical conductor embedded into the second adhesive layer, a second conductor surface of the second electrical conductor protruding from the second adhesive layer, and a second alloy bonding the second electrical conductor to the back side electrical contact such that current received at the solar cell from the back side electrical contact is provided by the electrical conductor.

In accordance with another aspect of the invention, there is provided a process for forming contacts in a semiconductor photovoltaic cell structure. The process includes distributing a plurality of individual portions of electrical contact paste in two dimensions across a front side surface of a semiconductor photovoltaic cell structure comprising respective doped portions of semiconductor material forming a photovoltaic junction; causing the individual portions of electrical contact paste to become embedded in the front side surface such that the individual portions of electrical contact paste form respective separate electrical contacts in the front side surface, the separate electrical contacts being in electrical contact with a corresponding doped portion of semiconductor material; and forming a back side electrical contact on a back side surface provided by the other of the respective portions of semiconductor material and in electrical contact therewith.

Distributing may include printing the individual portions of electrical contact paste on the front side surface.

Printing may include screen printing.

Distributing may include distributing the individual portions of electrical contact paste in two orthogonal directions across the surface.

Distributing may include distributing the individual portions of electrical contact paste evenly in the two orthogonal directions.

Distributing may include distributing the individual portions of electrical contact paste in an array.

Distributing may include distributing the individual portions of electrical contact paste in rows and columns.

Distributing may include causing the individual portions of electrical contact paste in alternate rows to lie in positions adjacent spaces between contacts in adjacent rows.

Causing the individual portions of electrical contact paste to become embedded in the front side surface may include heating the semiconductor photovoltaic cell structure with the portions of electrical contact paste thereon for a sufficient time and at a sufficient temperature to permit at least some of the electrical contact paste of each individual portion of electrical contact paste to enter a metallic phase and diffuse through the front side surface and into the portion of semiconductor material below the front side surface while leaving a sufficient portion of electrical contact paste in the metallic phase at the front side surface to act as an electrical contact surface of the separate electrical contact so formed.

The process may further include laying on the front side surface an electrode comprising an electrically insulating optically transparent film having an adhesive layer in which at least one electrical conductor is embedded such that a conducting surface thereof bearing a coating comprising a low melting point alloy protrudes from the adhesive layer, such that the conducting surface contacts a plurality of the electrical contacts formed in the semiconductor photovoltaic cell structure front side surface, and causing the low melting point alloy to melt to bond the conducting surface to the plurality of electrical contacts to electrically connect the electrical contacts to the electrical conductor to permit the electrical conductor to draw current from the solar cell through the electrical contacts.

The process may further include connecting the at least one electrical conductor to a bus.

The electrical contacts may be arranged in rows and columns and the electrode may include a plurality of electrical conductors arranged in parallel spaced apart relation. The electrode may be laid on the front side surface such that each electrical conductor is in contact with a plurality of the electrical contacts in a respective row or column.

The process may further involve connecting each of the electrical conductors to a common bus.

The process may further involve laying on the back side surface an electrode made of a second electrically insulating film having a second adhesive layer in which at least one second electrical conductor is embedded such that a second conducting surface thereof, bearing a second coating comprising a second low melting point alloy protrudes from the second adhesive layer, such that the second conducting surface contacts the back side electrical contact formed on the semiconductor photovoltaic cell structure back side surface and causing the second low melting point alloy to melt to bond the second conducting surface to the back side electrical contact to electrically connect the back side electrical contact to the second electrical conductor to permit the electrical conductor to supply current to the solar cell through the back side electrical contact.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

In drawings which illustrate embodiments of the invention,

FIG. 1 is a process diagram showing successive stages of a method for forming contacts on a semiconductor wafer, according to a first embodiment of the invention;

FIG. 2 is a cross sectional view of a semiconductor photovoltaic cell structure on which electrical contacts are to be formed by the method of FIG. 1;

FIG. 3. is a cross-sectional/perspective view of an apparatus according to an embodiment of another aspect of the invention, on which electrical contacts have been formed by the process of FIG. 1;

FIG. 4 is a top view of the apparatus shown in FIG. 3, showing electrical contacts having a rectangular shape;

FIG. 5 is a top view of an apparatus according to an alternate embodiment of the invention in which electrical contacts are circularly shaped;

FIG. 6 is a top view of an apparatus according to a third embodiment of the invention in which electrical contacts are rectangular and arranged in staggered rows;

FIG. 7 is a top view of an apparatus according to a fourth embodiment of the invention in which electrical contacts are circular and arranged in staggered rows;

FIG. 8 is a top view of an electrical contact having a star shape, in accordance with another embodiment of the invention;

FIG. 9 is a top view of an electrical contact having a cross shape in accordance with another embodiment of the invention;

FIG. 10 is a perspective view of an apparatus of the type shown in FIGS. 3, 4, 5, 6 or 7 showing electrodes being connected to front side electrical contacts and a back side aluminum contact layer; and

FIG. 11 is a side view of the apparatus shown in FIG. 10 after first and second electrodes have been affixed to said front side electrical contacts and back side aluminum contact layer, respectively.

### DETAILED DESCRIPTION

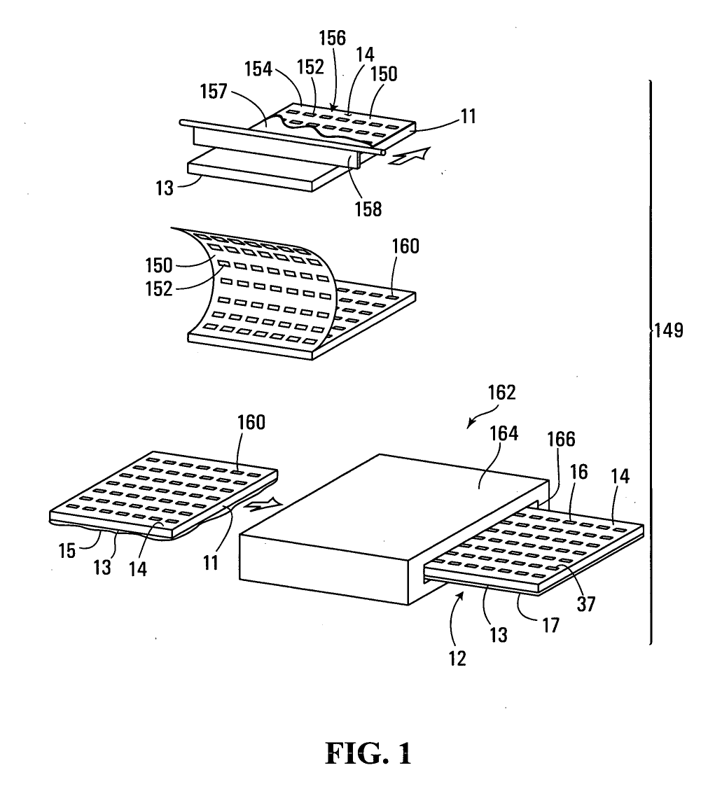

Referring to FIG. 1, a method according to a first embodiment of a first aspect of the invention, for forming electrical contacts in a semiconductor photovoltaic cell structure 11 is shown generally at 149.

Semiconductor Photovoltaic Cell Structure

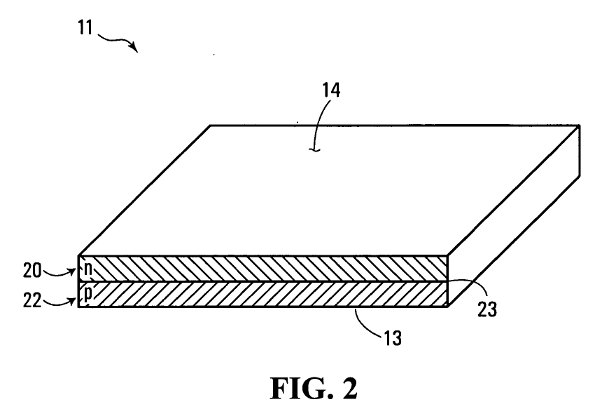

Referring to FIG. 2, in this embodiment the semiconductor photovoltaic cell structure 11 includes a silicon wafer into which has been diffused an n-type region 20 and a p-type region 22 which form a p-n junction 23. Alternatively, the n-type region 20 and the p-type region 22 may be reversed. In the embodiment shown, a front side surface 14 is provided by a surface of the n-type region 20 and the p-type region 22 is immediately adjacent the n-type region and defines a back side surface 13. In the embodiment shown, the n-type region has a thickness of approximately 0.6 micrometers and the p-type region has a thickness of approximately 200-600 micrometers.

Process for Forming Electrical Contacts

Referring back to FIG. 1, the process for forming electrical contacts involves distributing a plurality of individual portions of electrical contact paste in two dimensions across a front side surface of the semiconductor photovoltaic cell structure comprising respective doped portions of semiconductor material forming a photovoltaic junction, and causing the individual portions of electrical contact paste to become embedded in the front side surface such that the individual portions of electrical contact paste form respective separate electrical contacts in the front side surface. The separate electrical contacts are in electrical contact with a corresponding doped portion of semiconductor material forming the photovoltaic junction. The process further involves forming a back side electrical contact on the back side surface of the other of the respective portions of semiconductor material and in electrical contact therewith.

The process may begin by printing the individual portions of electrical contact paste 157 on the front side surface 14 such as by screen printing. Printing may involve screen printing wherein a mask 150 having a plurality of openings 152 arranged in a desired distribution, such as in an array of rows and columns 154 and 156, for example, is made to receive an amount of electrical contact paste 157 containing aluminum, silver, adhesive and silicon, in a solvent. A spreader 158 is then drawn across the mask 150 such that the paste 157 is distributed in two dimensions across the front side surface 14 through the openings 152 in the mask 150.

The spreader 158 may be moved in two orthogonal directions at successive points in time, for example, to distribute the electrical contact paste 157 in the two orthogonal directions across the front side surface 14. Automated machinery may be used to cause the electrical contact paste 157 to be distributed across the front side surface 14, through the openings 152 in the mask 150.

Various opening shapes and arrangements may be employed in the mask 150 to distribute the electrical contact paste in any desired distribution such as evenly in the two orthogonal directions, unevenly in the two orthogonal directions, in an array, in rows and columns, in staggered rows in which alternate rows lie in positions adjacent spaces between openings in adjacent rows, in gaussian distributions in one/or two directions, in distributions providing an increasing density of openings toward one side and/or end of the mask or any other distribution.

After the electrical contact paste has been distributed, the mask 150 may be separated from the surface, leaving the distributed electrical contact paste in separate isolated islands as shown at 160, for example, in the desired pattern of distribution, i.e., rows and columns, even rows and columns, uneven rows and columns, staggered rows and columns, etc.

Then, the electrical contact paste 160 is heated until dry. When the paste 160 is dry, back side metallization paste 15 is applied to an entire back side surface 13 of the structure 11 and is heated until dry. When both the electrical contact paste 160 and the back side metallization paste 15 have dried, the individual portions of electrical contact paste 160 are caused to become embedded in the front side surface 14 such that the individual portions of electrical contact paste form respective separate electrical contacts in the front side surface 14 and the back side metallization paste 15 is fused into the back side surface 13. In the embodiment shown, this action is shown generally at 162 in which the semiconductor cell structure 11 with the distributed electrical contact paste 160 and back side metallization paste 15 thereon is passed through an oven 164 where it is heated for a sufficient time and at a sufficient temperature to permit a small portion of the electrical contact paste of each individual portion of electrical contact paste to enter a metallic phase and diffuse through the front side surface 14 and into the semiconductor photovoltaic cell structure below, while leaving a sufficient portion (nearly all) of electrical contact paste 160 in the metallic phase exposed at the front side surface 14.

The electrical contact paste 160 forms electrical contacts 16 in the front side surface 14, the electrical contacts being in electrical contact with the n-type semiconductor material beneath the active side surface, but separate from other contacts. Each electrical contact 16 has an electrical contact surface 37 formed by the portion of electrical contact paste 160 in the metallic phase left on the front side surface 14. The electrical contacts 16 are thus intermittently positioned across the front side surface 14.

Similarly, the back side metallization paste 15 is fused to a back side surface 13 of the semiconductor photovoltaic cell structure 11 thereby creating a back surface field and provides a back side electrical contact 17.

In the embodiment shown, the oven 164 has an outlet 166 through which a completed semiconductor photovoltaic cell apparatus 12, having a front side surface 14 with a plurality of separate electrical contacts 16 embedded therein and a back side electrical contact 17 comprising a single large contact fused therein is provided.

Semiconductor Photovoltaic Cell Apparatus

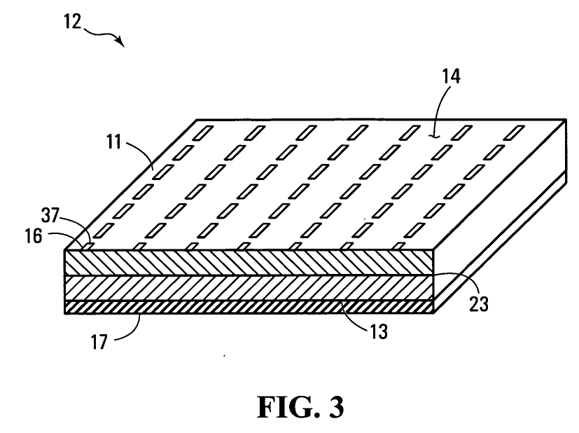

As a result of the process shown in FIG. 1, a completed semiconductor photovoltaic cell apparatus according to a first embodiment of the invention is produced, as shown generally at 12 in FIG. 3. The apparatus 12 comprises a semiconductor photovoltaic cell structure having a front side surface and a back side surface 13 provided by respective doped portions 20 and 22 of semiconductor material forming a photovoltaic junction 23, a plurality of electrical contacts 16 embedded in the front side surface 14 of the respective one of the portions of semiconductor material. The electrical contacts 16 are distributed in two dimensions across the surface 14, separated from each other, and in electrical contact with the respective one of the portions of semiconductor material. The apparatus further comprises a back side electrical contact 17 on the back side surface of the other of the respective portions of semiconductor material and in electrical contact therewith.

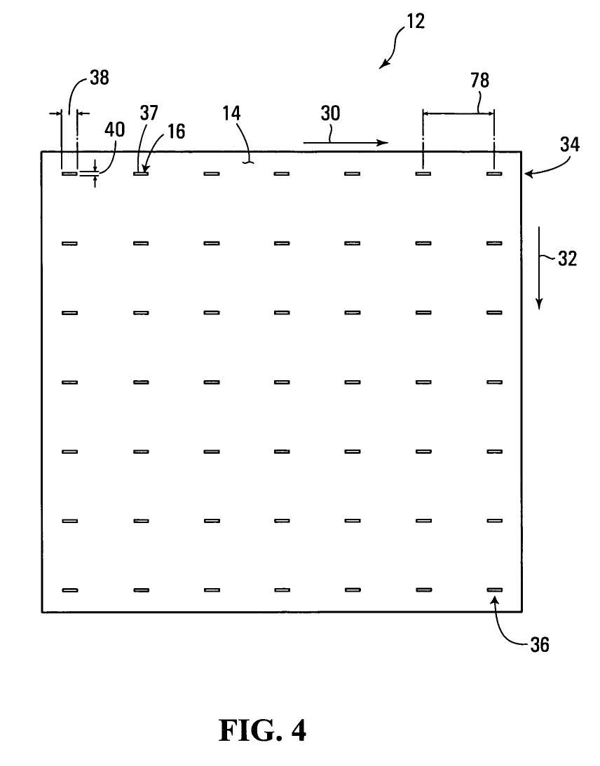

Referring to FIG. 4, in the embodiment shown, the electrical contacts 16 of the completed semiconductor cell apparatus 12 are distributed in two dimensions across the front side surface 14, the distribution being established by the mask 150 shown in FIG. 1. The electrical contacts 16 are separate from each other, although they are electrically connected to the semiconductor photovoltaic structure under the front side surface 14.

In the embodiment shown the electrical contacts 16 are distributed in two orthogonal directions, shown generally at 30 and 32 and, in this embodiment, they are distributed evenly in these two directions. In other words, the spacing between the contacts in the first direction 30 is uniform and the spacing between the contacts in the second direction 32 is also uniform. In the embodiment shown, the contacts are arranged in rows and columns, a first row being shown generally at 34 and a first column being shown generally at 36. The contacts are thus arranged in an array in this embodiment.

Alternatively, other distributions of contacts may have been laid by the mask 150 shown in FIG. 1. For example, the density of contacts on the front side surface 14 may increase in the first direction 30, in the second direction 32 or in both directions. Or a gaussian or any other distribution in the first and/or second directions may be used.

In the embodiment shown, the electrical contacts 16 have an electrical contact surface 37 having an elongated rectangular shape, having a length 38 of between approximately 0.5 mm to approximately 2 mm and a width 40 of between approximately 0.1 mm to 1 mm. In the embodiment shown, each contact surface 37 has generally the same length and width dimensions and is oriented in generally the same direction, i.e., aligned in the first orthogonal direction 30. It will be appreciated that each contact 16 is physically isolated in that it is set apart from each other electrical contact. However, each contact 16 is also in electrical contact with the n-type material under the front side surface 14 to make electrical connection with the semiconductor photovoltaic cell structure 11. Therefore, while the electrical contacts 16 appear physically separate when viewed from the front side surface 14 of the solar cell structure, they are in fact electrically connected to the semiconductor photovoltaic cell structure beneath the front side surface 14. In one sense, the contacts 16 appear to be intermittent “fingers” across the front side surface 14 rather than continuous linear fingers as in the prior art.

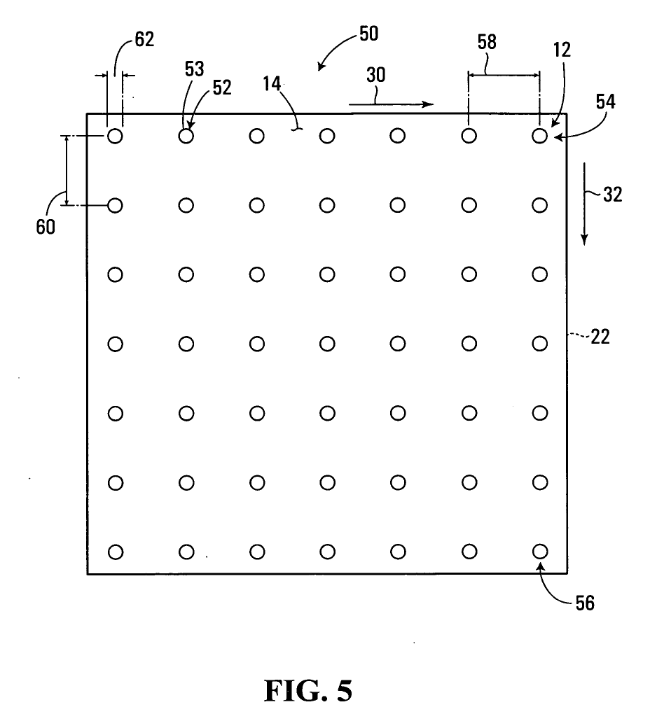

Referring to FIG. 5, a semiconductor photovoltaic cell apparatus according to a second embodiment of the invention is shown generally at 50. In this embodiment, the semiconductor photovoltaic cell apparatus is identical to that shown at 12 in FIG. 3, with the exception that it has electrical contacts 52 with circularly shaped contact surfaces 53 instead of rectangular contacts as shown in FIG. 4.

Referring back to FIG. 5, in this embodiment, each electrical contact 52 is distributed in the same two orthogonal directions 30 and 32 across the surface of the semiconductor photovoltaic structure and is distributed evenly in these two orthogonal directions. Again, the electrical contacts 52 are arranged in rows and columns, a first row being shown generally at 54 and a first column being shown generally at 56. Also, in this embodiment, the electrical contacts 52 are spaced apart by a distance 58 in the first orthogonal direction and a second distance 60 in the second orthogonal direction 32.

These distances may be equal or different. Again, alternatively, the contacts 52 may be distributed across the front side surface 14 with increasing density in the first and/or second directions 30 and 32 or more generally with constant or changing density in these two directions.

As stated, each electrical contact 52 has a circular contact surface 53, having a diameter 62 of approximately 1 millimetre. Again, each electrical contact 52 is embedded in the front side surface 14 and into the n-type layer 20 of the semiconductor photovoltaic cell structure 11. Circular openings in the mask 150 described in FIG. 1, may be used to make electrical contacts having circular contact surfaces 53 as shown.

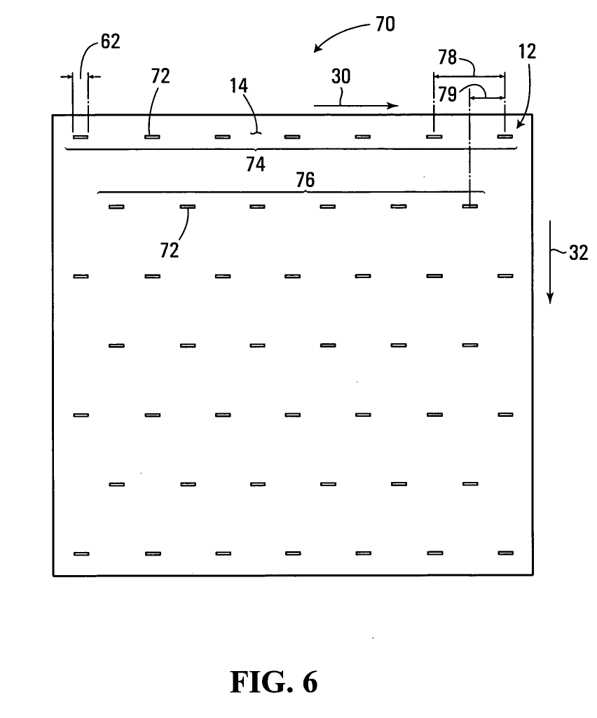

Referring to FIG. 6, a semiconductor photovoltaic cell apparatus according to a third embodiment of the invention is shown generally at 70. This apparatus 70 includes the same semiconductor photovoltaic cell structure 11 as shown in FIG. 2 and includes a plurality of rectangular contacts, one of which is shown at 72, distributed in the same two orthogonal directions 30 and 32 across the front side surface 14 of the semiconductor photovoltaic cell structure. In this embodiment, the contacts 72 are arranged in a plurality of staggered rows, one of which is shown generally at 74 and a second of which is shown at 76. In this embodiment, there are spaces 78 between the contacts 72 of a given row, such as row 74, and the contacts of each row have the same spacing 78. However, the contacts 72 of the second row 76 are arranged to align approximately centrally between contacts in the adjacent row, i.e., the first row 74. This is repeated throughout all rows of contacts such that the contacts of alternate rows are arranged to lie in positions adjacent spaces between contacts in adjacent rows. In other words, adjacent rows are staggered by a distance 79. The dimensions and spacing of the individual rectangular contacts 72 have the same shape, dimensions and spacing as the contacts 16 in FIG. 4.

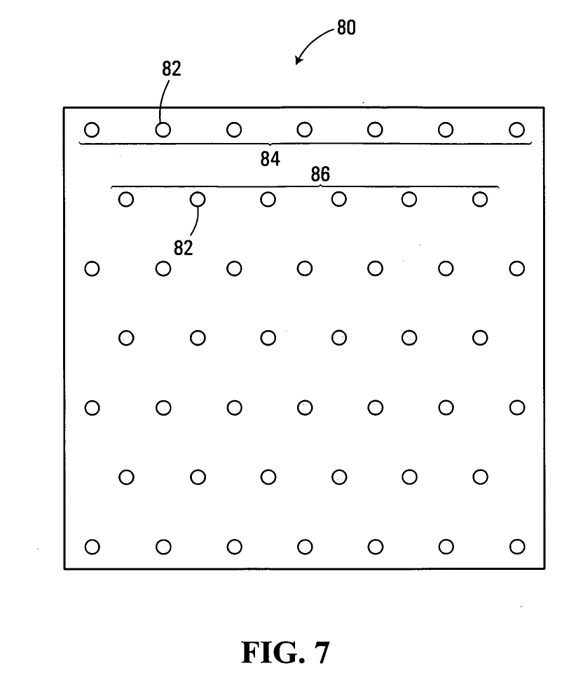

Referring to FIG. 7, a semiconductor photovoltaic cell structure apparatus according to a fourth embodiment of the invention is shown generally at 80. The apparatus 80 of this embodiment is similar to that of the embodiment described above (in FIG. 6) in that it includes contacts 82 that are arranged in staggered rows, one of which is shown at 84 and a second of which is shown at 86, such that the contacts of alternate rows are arranged to lie in positions adjacent spaces between contacts in adjacent rows. Otherwise, the contacts 82 in any given row shown in FIG. 7 have the same shape, dimensions and spacing as the contacts 52 shown in FIG. 5.

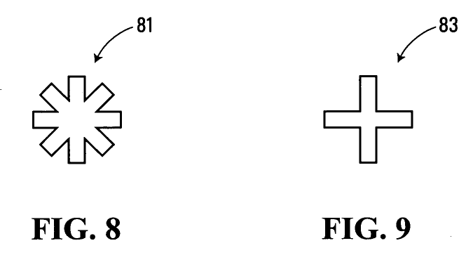

Referring to FIGS. 8 and 9, the contact surfaces of the electrical contacts may have a star shape such as shown at 81 in FIG. 8, an x shape as shown at 83 in FIG. 9, or any other desired shape that is surrounded on all sides by a void, space, insulator or semiconductor between it and the next nearest contact.

Solar Cell Unit

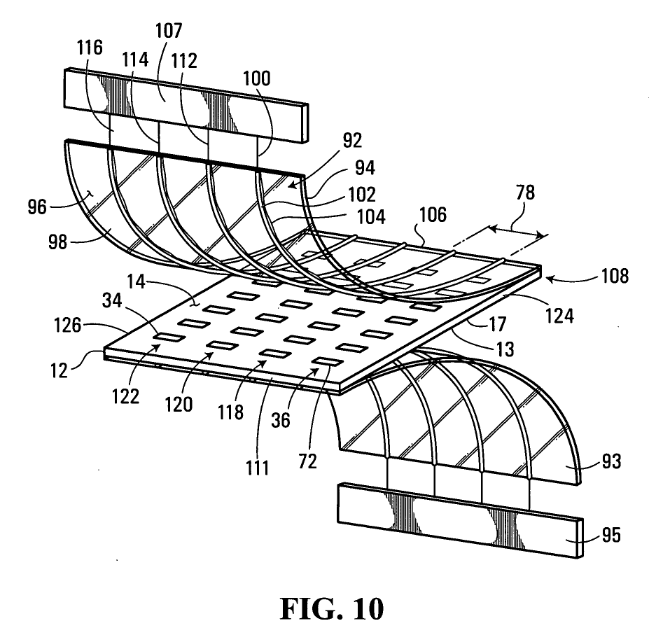

Referring to FIG. 10, a semiconductor photovoltaic cell apparatus according to any of the apparatuses described in FIGS. 3 through 7 may be made into a “solar cell unit” and connectable to an electrical circuit by securing a first electrode such as shown at 92 to the front side surface 14 to contact the electrical contacts 72 and by securing a second electrode 93 to the back side electrical contact 17.

In the embodiment shown in FIG. 10, the first electrode 92 comprises an electrically insulating optically transparent film 94 having a surface 96 and an adhesive layer 98 on the surface. The electrode 92 further includes at least one electrical conductor 100 embedded into the adhesive layer 98 and having a conductor surface 102 protruding from the adhesive layer. An alloy 104 is used to bond the electrical conductor 100 to at least some of the electrical contacts 72 such that current collected from the semiconductor photovoltaic cell apparatus by the electrical contacts is gathered by the electrical conductor.

In the embodiment shown, the alloy bonding the electrical conductor 100 to at least some of the electrical contacts may include a material that may be heated to solidify and electrically bond and connect the electrical conductor 100 to a plurality of electrical contacts 72 in a row. The alloy may be a coating on the conductor surface 102, for example.

As shown in FIG. 10, the electrode 92 includes a plurality of conductors including conductor 100 and conductors 112, 114 and 116. The conductors 100, 112, 114 and 116 are, in this embodiment, laid out in parallel spaced apart relation on the adhesive layer of the electrode with the spacing corresponding to the spacing 78, for example, between adjacent columns 36, 118, 120 and 122 of contacts on the front side surface 14 of the semiconductor cell apparatus 12. In effect therefore, in this embodiment the electrical contacts 72 are arranged in rows and columns and the electrode 92 comprises a plurality of electrical conductors 100, 112, 114 and 116 arranged in parallel spaced apart relation such that when the electrode is applied to the front side surface 14 of the semiconductor cell apparatus 12, the electrical conductors are in contact with a plurality of electrical contacts 72 in a respective column 36, 118, 120 and 122.

Initially, the first electrode 92 may be curled as shown in FIG. 10 to align a rear edge 106 of the electrode with a rear edge 108 of the semiconductor cell apparatus 12 and then the film 94, with its adhesive layer 98 with the conductors 100, 112, 114 and 116 embedded therein, may be pressed downwardly onto the front side surface 14 of the semiconductor cell apparatus 12 to roll out the electrode 92 and secure the adhesive layer to the front side surface 14, such that the electrical conductors 100, 112, 114 and 116 come into contact with successive electrical contacts 72 of respective columns of contacts between the rear edge 108 of the semiconductor cell structure and a front edge 111 of the semiconductor photovoltaic apparatus.

Alternatively, the rear edge 106 of the first electrode 92 may be aligned with a right hand side edge 124 of the semiconductor cell apparatus 12 and rolled out across the front side surface 14 of the semiconductor cell apparatus in a manner such that the conductors 100, 112, 114 and 116 contact a plurality of electrical contacts 72 in a respective row of electrical contacts 72 on the front side surface 14 of the semiconductor cell apparatus 12.

In the embodiment shown, the electrical conductors 100, 112, 114 and 116 extend beyond the optically transparent film 94 and are terminated in contact with a common bus 107, which may be formed of metallic foil, such as copper, for example.

Further details of general and alternate constructions of the first electrode 92 may be obtained from applicant's International Patent Application published under International Publication Number WO 2004/021455A1, which is incorporated herein by reference.

The second electrode 93 is similar to the first electrode 92 in all respects and in fact a plurality of the above described first electrodes may be pre-manufactured and individual ones applied to the front side surface 14 or back side electrical contact 17 as desired. It should be noted however that the second electrode 93 need not be optically transparent like the first electrode since the back side is not intended to receive light.

The back side electrical contact 17 has no rows of contacts, but rather is a single flat planar contact extending across the entire back side surface 13 of the semiconductor cell structure. The conductors 100, 112, 114 and 116 of the second electrode 93 are prepared with the low melting point alloy paste and the electrode 93 is adhesively secured to the back side electrical contact 17 such that the low melting point alloy is operable to bond the conductors to the back side electrical contact 17 when sufficiently heated.

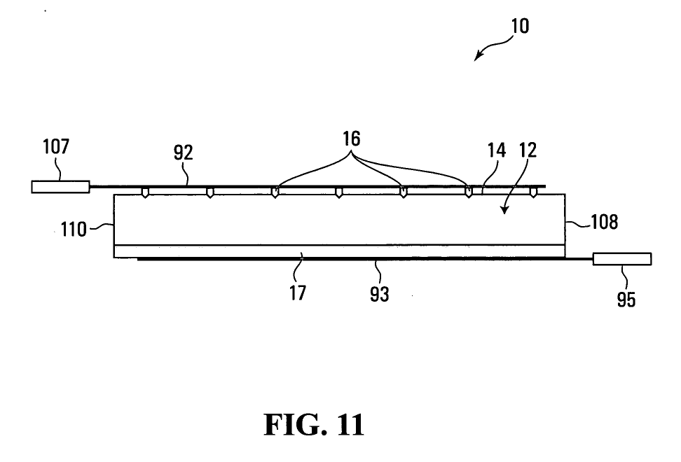

As shown in FIG. 11, the second electrode 93 may be applied to the back side electrical contact 17 such that a bus 95 thereof will lie adjacent the rear edge 108 of the semiconductor cell apparatus 12 while the bus 107 of the first electrode 92 is located adjacent the front edge 110 of the semiconductor cell apparatus 12. This permits adjacent solar cell structures to be connected in series, for example, simply by placing them adjacent to each other and allowing the bus bars 95 and 107 of adjacent semiconductor cell structures to overlap each other, in contact with each other.

After the first electrode 92 is laid on top of the front side surface 14 such that the conductors 100, 112, 114 and 116 contact respective columns 36, 118, 120 and 122 of contacts 72, for example, and the second electrode 93 is laid on the back side electrical contact 17, the resulting apparatus may be regarded as an assembly. The assembly is then heated such that the low melting point alloy associated with the first electrode 92 is caused to melt to bond the conducting surfaces of respective conductors 100, 112, 114 and 116 of the first electrode 92 to contact surfaces of respective rows of electrical contacts 72 to electrically connect the electrical contacts to the electrical conductors and to cause the low melting point alloy associated with the second electrode 93 to bond the conducting surfaces of respective conductors to the back side electrical contact 17, to permit the electrical conductors to pass current through the solar cell through the electrical contacts. Once the low melting point alloy has completed this bonding, a completed solar cell as shown at 10 in FIG. 11 ready to be used in an electrical circuit and has thus been produced.

A solar cell produced as described above may provide several advantages. Due to the reduced area occupied by the electrical contacts in the front side surface, there is less shading of the p-n junction which can cause as much as 5-10% more electric current to pass through the solar cell. In addition, as there is less area occupied by metallization and the back surface field area is not interrupted by silver/aluminum fingers, the cell can generate a voltage of up to 3% more than conventional cells. Overall these two effects may increase the efficiency of the solar cell by up to 10-15%. Furthermore, the production costs of solar cells of the type described are lower than with conventional solar cells because a substantially less amount of silver is used in forming contacts.

While specific embodiments of the invention have been described and illustrated, such embodiments should be considered illustrative of the invention only and not as limiting the invention as construed in accordance with the accompanying claims.

1. A photovoltaic apparatus comprising.
a semiconductor photovoltaic cell structure having a front side surface and a back side surface provided by respectively doped portions of semiconductor material forming a photovoltaic junction;
a plurality of electrical contacts embedded in said front surface of a respective one of said portion of semiconductor material, said electrical contacts being distributed in two dimensions across said surface and separated from each other and in electrical contact with said respective one of said portions of semiconductor material; and
a back side electrical contact on said back side surface of the other of said respective portions of semiconductor material and in electrical contact therewith.

2. The photovoltaic apparatus of claim 1 wherein said electrical contacts are distributed in two orthogonal directions across said surface.

3. The photovoltaic apparatus of claim 2 wherein said electrical contacts are distributed evenly in said two orthogonal directions.

4. The photovoltaic apparatus of claim 1 wherein said electrical contacts are arranged in an array.

5. The photovoltaic apparatus of claim 1 wherein said electrical contacts are arranged in rows and columns.

6. The photovoltaic apparatus of claim 5 wherein contacts of alternate rows are arranged to lie in positions adjacent spaces between contacts in adjacent rows.

7. The photovoltaic apparatus of claim 1 wherein generally each of said electrical contacts has a contact surface facing generally normal to said front side surface and operable to be connected to a conductor.

8. The photovoltaic apparatus of claim 7 wherein said contact surface has a generally rectangular shape.

9. The photovoltaic apparatus of claim 7 wherein said contact surface has a generally circular shape.

10. The photovoltaic apparatus of claim 7 wherein said contact surface has a star shape.

11. A solar cell apparatus comprising the photovoltaic apparatus of claim 1 and further comprising a first electrode for contacting said electrical contacts, said electrode comprising an electrically insulating optically transparent film having a surface, an adhesive layer on said surface of said film, at least one electrical conductor embedded into the adhesive layer and having a conductor surface protruding from said adhesive layer, and an alloy bonding said electrical conductor to at least some of said electrical contacts such that current collected from said solar cell by said electrical contacts is gathered by said electrical conductor.

12. The solar cell apparatus of claim 11 wherein said electrical conductor is connected to a common bus.

13. The solar cell apparatus of claim 11 wherein said electrical contacts are arranged in rows and columns and wherein said electrode comprises a plurality of electrical conductors arranged in parallel spaced apart relation and wherein said electrical conductors are in contact with a plurality of said electrical contacts in a respective row or column.

14. The solar cell apparatus of claim 13 wherein each of said electrical conductors is connected to a common bus.

15. The solar cell apparatus of claim 11 further comprising a second electrode for contacting said back side electrical contact, said second electrode comprising a second electrically insulating film having a second surface, a second adhesive layer on said second surface of said second film, at least one second electrical conductor embedded into the second adhesive layer and having a second conductor surface protruding from said second adhesive layer, and a second alloy bonding said second electrical conductor to said back side electrical contact such that current received at said solar cell from said back side electrical contact is provided by said electrical conductor.

16. A process for making the photovoltaic apparatus of claim 1, the process comprising:
distributing a plurality of individual portions of electrical contact paste in two dimensions across said front side surface of said semiconductor photovoltaic cell structure; and
causing said individual portions of electrical contact paste to become embedded in said front side surface such that said individual portions of electrical contact paste form respective separate electrical contacts in said front side surface; and
forming said back side electrical contact on said back side surface.

17. The process of claim 16 wherein distributing comprises printing said individual portions of electrical contact paste on said front side surface.

18. The process of claim 17 wherein printing comprises screen printing.

19. The process of claim 16 wherein distributing comprises distributing said individual portions of electrical contact paste in two orthogonal directions across said surface.

20. The process of claim 19 wherein distributing comprises distributing said individual portions of electrical contact paste evenly in said two orthogonal directions.

21. The process of claim 16 wherein distributing comprises distributing said individual portions of electrical contact paste in an array.

22. The process of claim 16 wherein distributing comprises distributing said individual portions of electrical contact paste in rows and columns.

23. The process of claim 22 wherein distributing comprises causing said individual portions of electrical contact paste in alternate rows to lie in positions adjacent spaces between contacts in adjacent rows.

24. The process of claim 16 wherein causing said individual portions of electrical contact paste to become embedded comprises heating said semiconductor photovoltaic cell structure with said portions of electrical contact paste thereon for a sufficient time and at a sufficient temperature to permit at least some of said electrical contact paste of each individual portion of electrical contact paste to enter a metallic phase and diffuse through said front side surface and into the portion of semiconductor material below the front side surface while leaving a sufficient portion of electrical contact paste in the metallic phase at said front side surface to act as an electrical contact surface of said separate electrical contact so formed.

25. A process for forming a solar cell apparatus, the process comprising the process of claim 16 further comprising:
laying a first electrode comprising a first electrically insulating optically transparent film having a first adhesive layer in which at least one first electrical conductor is embedded such that a first conducting surface thereof, bearing a first coating comprising a first low melting point alloy protrudes from said adhesive layer, such that said first conducting surface contacts a plurality of said electrical contacts formed in said semiconductor photovoltaic cell structure front side surface; and
causing said first low melting point alloy to melt to bond said first conducting surface to said plurality of electrical contacts to electrically connect said electrical contacts to said first electrical conductor to permit said first electrical conductor to draw current from said solar cell apparatus through said first electrical contacts.

26. The process of claim 25 further comprising connecting said at least one electrical conductor to a bus.

27. The process of claim 25 wherein said electrical contacts are arranged in rows and columns and wherein said electrode comprises a plurality of electrical conductors arranged In parallel spaced apart relation and wherein said electrode is laid on said front side surface such that each electrical conductor is in contact with a plurality of said electrical contacts in a respective row or column.

28. The process of claim 27 further comprising connecting each of said electrical conductors to a common bus.

29. The process of claim 25 further comprising:
laying a second electrode comprising: a second electrically insulating film having a second adhesive layer in which at least one second electrical conductor is embedded such that a second conducting surface thereof, bearing a second coating comprising a second low melting point alloy protrudes from said second adhesive layer, such that said second conducting surface contacts said back side electrical contact formed on said semiconductor photovoltaic cell structure back side surface; and
causing said second low melting point alloy to melt to bond said second conducting surface to said back side electrical contact to electrically connect said back side electrical contact to said second electrical conductor to permit said electrical conductor to supply current to said solar cell apparatus through said back side electrical contact.
